(19) United States
(12) Patent Application Publication
(10) Pub. No.: US 2025/0107330 A1
(43) Pub. Date: Mar. 27, 2025

(54) DISPLAY DEVICE

(71) Applicant: LG Display Co., Ltd., Seoul (KR)

(72) Inventors: KangIl KIM, Seoul (KR); Seongkwang KIM, Goyang-si (KR); Seongku LEE, Seoul (KR)

(21) Appl. No.: 18/883,673

(22) Filed: Sep. 12, 2024

(30) Foreign Application Priority Data
Sep. 26, 2023 (KR) 10-2023-0128871

(51) Int. Cl. H10K 59/121; H10K 59/12; H10K 59/122

(52) U.S. Cl. CPC H10K 59/1213; H10K 59/1201; H10K 59/122

(57) ABSTRACT

Provided is a display device. The display device includes a substrate including a plurality of subpixels. The device includes a driving transistor in each of the plurality of subpixels. The device includes a passivation layer on the driving transistor. The device includes a planarization layer on the passivation layer. The device includes a contact hole in the passivation layer and the planarization layer to expose a source electrode of the driving transistor. The device includes a first anode on a top surface of the planarization layer and the contact hole. The device includes a first bank covering an edge of the first anode. The device includes a second bank on the first anode in the contact hole, in which a height of the second bank is equal to or smaller than a height of the planarization layer. Therefore, the degree of design freedom and the aperture ratio may be improved.

### CROSS-REFERENCE TO RELATED APPLICATIONS

This application claims the priority of Korean Patent Application No. 10-2023-0128871 filed on Sep. 26, 2023, in the Korean Intellectual Property Office, the disclosure of which is incorporated herein by reference.

### BACKGROUND

### Technical Field

The present specification relates to a display device, and more particularly, to a display device with an improved aperture ratio and an improved degree of design freedom.

### Description of the Related Art

The range of application of liquid crystal display (LCD) devices and organic light-emitting display (OLED) devices, which have been widely used until now, are gradually expanding.

An organic light-emitting display (OLED) device does not require a separate light source, unlike a liquid crystal display (LCD) device having a backlight. The advantages of the organic light-emitting display device are that the organic light-emitting display device may be manufactured to be lightweight and thin, a process may be facilitated, and power consumption is low because the organic light-emitting display device may be operated by a low voltage. Among other things, the organic light-emitting display device may have an autonomous light-emitting element, and layers of the organic light-emitting display device may be configured by thin organic films. The advantages of the organic light-emitting display device are that the organic light-emitting display device may have excellent flexibility and elasticity in comparison with other display devices.

### BRIEF SUMMARY

Various embodiments of the present specification provide a high-resolution display device.

Various embodiments of the present specification provide a display device with an improved degree of design freedom.

Various embodiments of the present specification provide a display device with an improved aperture ratio.

Technical benefits of the present disclosure are not limited to the above-mentioned benefits, and other benefits, which are not mentioned above, can be clearly understood by those skilled in the art from the following descriptions.

A display device according to one embodiment of the present specification may include: a substrate including a plurality of subpixels; a driving transistor in each of the plurality of subpixels; a passivation layer on the driving transistor; a planarization layer on the passivation layer; a contact hole formed in the passivation layer and the planarization layer to expose a source electrode of the driving transistor; a first anode on a top surface of the planarization layer and the contact hole; a first bank configured to cover an edge of the first anode; and a second bank disposed on the first anode in the contact hole, in which a height of the second bank is equal to or smaller than a height of the planarization layer. Therefore, the degree of design freedom and the aperture ratio may be improved.

Other detailed matters of the exemplary embodiments are included in the detailed description and the drawings.

According to the embodiment of the present specification, the second bank is disposed in the contact hole, such that the abnormal light-emitting area caused by the step difference of the planarization layer is not visually recognized, which may improve the display quality.

According to the embodiment of the present specification, the second bank is disposed in the contact hole by using the residue, such that a process margin does not need to be ensured between the planarization layer and the second bank, which may improve the degree of design freedom.

According to the embodiment of the present specification, the second bank is disposed only in the contact hole, such that the non-light-emitting area of the contact area may be minimized, and the aperture ratio may be improved.

According to the embodiment of the present specification, the second anode having a flat surface may be further disposed on the second bank in the contact area, such that light may be emitted even in the contact area, which may improve the aperture ratio.

The effects according to the present disclosure are not limited to the contents exemplified above, and more various effects are included in the present specification.

A method of manufacturing the display device according to one embodiment of the present specification may comprises: etching a part of the passivation layer and a part of the planarization layer to form the contact hole; depositing the first anode on the planarization layer and the contact hole; forming a bank coating layer by coating the planarization layer and the contact hole, wherein a height of the bank coating layer in the contact hole is larger than a height of the bank coating layer on the planarization layer; etching the bank coating layer to form the first bank and the second bank.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is a schematic configuration view of a display device according to an embodiment of the present specification;

FIG. 2 is a cross-sectional view taken along line II-II′ in FIG. 1;

FIG. 3 is a cross-sectional view of a display device according to another embodiment of the present specification;

FIG. 4 is a cross-sectional view of a display device according to still another embodiment of the present specification;

FIG. 5 is a cross-sectional view of a display device according to yet another embodiment of the present specification;

FIG. 6 is a cross-sectional view of a display device according to a comparative example; and

FIGS. 7A to 7E are process diagrams for explaining a method of manufacturing the display device according to the embodiment of the present specification.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, dimensions (e.g., length, width, height, thickness, radius, diameter, area, etc.), ratios, angles, numbers, and the like illustrated in the accompanying drawings for describing the exemplary embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on,” “above,” “below,” and “next,” one or more parts may be positioned between the two parts unless the terms are used with the term “immediately” or “directly.”

When an element or layer is disposed “on” another element or layer, another layer or another element may be interposed directly on the other element or therebetween.

Although the terms “first,” “second,” and the like are used for describing various components, these components are not confined by these terms. These terms are merely used for distinguishing one component from the other components. Therefore, a first component to be mentioned below may be a second component in a technical concept of the present disclosure.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

The features of various embodiments of the present disclosure can be partially or entirely adhered to or combined with each other and can be interlocked and operated in technically various ways, and the embodiments can be carried out independently of or in association with each other.

Hereinafter, a display device according to exemplary embodiments of the present disclosure will be described in detail with reference to accompanying drawings.

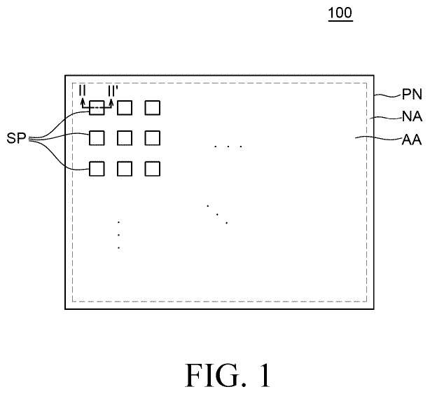

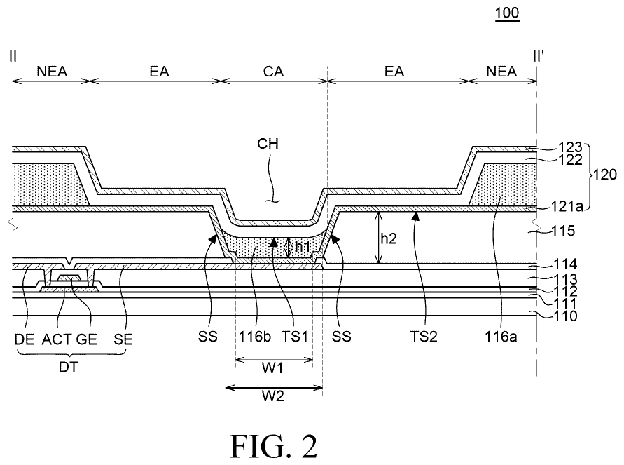

FIG. 1 is a schematic configuration view of a display device according to an embodiment of the present specification. FIG. 2 is a cross-sectional view taken along line II-II′ in FIG. 1. For convenience of description, FIG. 1 illustrates only a display panel PN among various constituent elements of a display device 100.

With reference to FIG. 1, the display device 100 may include the display panel PN including a plurality of subpixels SP.

The display panel PN is configured to display images to a user and may include the plurality of subpixels SP. In the display panel PN, a plurality of scan lines and a plurality of data lines may intersect one another, and each of the plurality of subpixels may be connected to the scan line and the data line. In addition, although not illustrated in the drawings, the plurality of subpixels SP may be respectively connected to a high-potential power line, a low-potential power line, a reference line, and the like.

The display panel PN may have a display area AA, and a non-display area NA configured to surround the display area AA.

The display panel PN refers to an organic display panel using an organic light-emitting element that injects electrons and holes into a light-emitting layer from a cathode for injecting electrons and an anode for injecting holes and emits light when excitons, which are made by coupling the injected electrons and holes, fall from an excited state to a ground state.

The display area AA is an area of the display device 100 in which images are displayed. The display area AA may include a plurality of subpixels SP constituting a plurality of pixels, and a circuit configured to operate the plurality of subpixels SP. The plurality of subpixels SP is minimum units that constitute the display area AA. The n subpixels SP may constitute a single pixel. Specifically, each of the subpixels SP is an element for displaying one color. The subpixel SP may be defined as an area in which a plurality of scan lines disposed in a first direction and a plurality of data lines disposed in a second direction different from the first direction intersect each other. In this case, the first direction may be a horizontal direction (X-axis direction) in FIG. 1, and the second direction may be a vertical direction (Y-axis direction) in FIG. 1. However, the present specification is not limited thereto. The subpixels SP may each include a light-emitting area EA from which light is emitted, and a non-light-emitting area NEA from which no light is emitted.

A light-emitting element, a transistor for operating the light-emitting element, and the like may be disposed in each of the plurality of subpixels SP. The light emitting elements may be differently defined depending on the type of display panel. For example, in case that the display panel is an organic light-emitting display panel, the light-emitting element may be an organic light-emitting diode (OLED).

A plurality of lines for transmitting various types of signals to the plurality of subpixels SP may be disposed in the display area AA. Although not illustrated in the drawings, for example, the plurality of lines may include a plurality of data lines for supplying data voltages to the plurality of subpixels SP, and a plurality of scan lines for supplying scan signals to the plurality of subpixels SP. The plurality of scan lines may extend in one direction in the display area AA and be connected to the plurality of subpixels SP. The plurality of data lines may extend in a direction different from one direction in the display area AA and be connected to the plurality of subpixels SP. In addition, a low-potential power line, a high-potential power line, and the like may be further disposed in the display area AA. However, the present specification is not limited thereto.

The non-display area NA may be defined as an area in which no image is displayed, i.e., an area extending from the display area AA. The non-display area NA may include link lines and pad electrodes for transmitting signals to the subpixels SP in the display area AA. Alternatively, the non-display area NA may include drive ICs such as gate drivers IC and data drivers IC.

However, the non-display area NA may be positioned on a rear surface of the display panel PN, i.e., a surface on which the subpixel SP is not present. Alternatively, the non-display area NA may be excluded. However, the present specification is not limited to the configuration illustrated in the drawings.

With reference to FIGS. 1 and 2, the display panel PN may include a substrate 110, a buffer layer 111, a gate insulation layer 112, an interlayer insulation layer 113, a passivation layer 114, a planarization layer 115, a first bank 116a, a second bank 116b, a light-emitting element 120, and a contact hole CH.

The substrate 110 is a support member for supporting other components of the display device 100 and may be made of an insulating material. For example, the substrate 110 may be made of glass, resin, or the like. In addition, the substrate 110 may include plastic such as polymer or polyimide (PI) and may be made of a material having flexibility.

The buffer layer 111 may be disposed on the substrate 110. The buffer layer 111 may reduce the penetration of moisture or impurities through the substrate 110. For example, the buffer layer 111 may be configured as a single layer or multilayer made of silicon oxide (SiOx) or silicon nitride (SiNx). However, the present specification is not limited thereto. However, the buffer layer 111 may be excluded in accordance with the type of substrate 110 or the type of driving transistor. However, the present specification is not limited thereto.

A driving transistor DT including an active layer ACT, a gate electrode GE, a source electrode SE, and a drain electrode DE may be disposed on the buffer layer 111.

First, the active layer ACT of the driving transistor DT may be disposed on the buffer layer 111. The active layer ACT may be made of a semiconductor material such as an oxide semiconductor, amorphous silicon, or polysilicon. However, the present specification is not limited thereto. In addition, although not illustrated in the drawings, in addition to the driving transistor DT, other transistors, such as a switching transistor, a sensing transistor, and a light emission control transistor, may be additionally disposed. The active layers of these transistors may be made of a semiconductor material such as an oxide semiconductor, amorphous silicon, or polysilicon. However, the present specification is not limited thereto. In addition, the active layers of the transistors, such as the driving transistor DT, the switching transistor, the sensing transistor, and the light emission control transistor, which are included in the pixel circuits, may be made of the same material or different materials.

The gate insulation layer 112 may be disposed on the active layer ACT. The gate insulation layer 112 may be an insulation layer for electrically insulating the active layer ACT and the gate electrode GE. The gate insulation layer 112 may be configured as a single layer or multilayer made of silicon oxide (SiOx) or silicon nitride (SiNx). However, the present specification is not limited thereto.

The gate electrode GE may be disposed on the gate insulation layer 112. The gate electrode GE may be made of an electrically conductive material, for example, copper (Cu), aluminum (Al), molybdenum (Mo), nickel (Ni), titanium (Ti), chromium (Cr), or an alloy thereof. However, the present specification is not limited thereto.

The interlayer insulation layer 113 may be disposed on the gate electrode GE. The contact hole CH, through which the source electrode SE and the drain electrode DE are connected to the active layer ACT, may be formed in the interlayer insulation layer 113. The interlayer insulation layer 113 may be an insulation layer for protecting components disposed below the interlayer insulation layer 113. The interlayer insulation layer 113 may be configured as a single layer or multilayer made of silicon oxide (SiOx) or silicon nitride (SiNx). However, the present specification is not limited thereto.

The source electrode SE and the drain electrode DE, which are electrically connected to the active layer ACT, may be disposed on the interlayer insulation layer 113. The source electrode SE and the drain electrode DE may each be made of an electrically conductive material, for example, copper (Cu), aluminum (Al), molybdenum (Mo), nickel (Ni), titanium (Ti), chromium (Cr), or an alloy thereof. However, the present specification is not limited thereto.

The passivation layer 114 may be disposed on the source electrode SE and the drain electrode DE. The passivation layer 114 is an insulation layer for protecting the components disposed below the passivation layer 114. For example, the passivation layer 114 may be made of an insulating inorganic material such as silicon oxide (SiOx) or silicon nitride (SiNx). In addition, the passivation layer 114 may be made of an insulating organic material or the like. However, the present specification is not limited thereto.

The planarization layer 115 may be disposed on the passivation layer 114. The planarization layer 115 may planarize an upper portion of the pixel circuit including the driving transistor DT. The planarization layer 115 may be configured as a single layer or multilayer and made of benzocyclobutene or an acrylic-based organic material, for example. However, the present specification is not limited thereto.

The plurality of light-emitting elements 120 is provided on the planarization layer 115 and respectively disposed in the plurality of subpixels SP. The light-emitting elements 120 may be elements configured to emit light by the current and include a red light-emitting element configured to emit red light, a green light-emitting element configured to emit green light, and a blue light-emitting element configured to emit blue light. A combination of the light-emitting elements 120 may implement various colors including white. For example, the light-emitting element 120 may be an organic light-emitting diode. However, the present specification is not limited thereto.

The contact hole CH with an inversely tapered shape is formed in the passivation layer 114 and the planarization layer 115. For example, the contact hole CH may be disposed in the light-emitting area EA. However, the present specification is not limited thereto. The source electrode SE of the driving transistor DT and a first anode 121a may be electrically connected through the contact hole CH. That is, the contact hole CH may be disposed to expose the source electrode SE. In this case, the contact hole CH may be disposed to expose a part of a top surface of the passivation layer 114. Therefore, a step difference may be formed between the passivation layer 114 and the planarization layer 115.

The first anode 121a may be disposed on the planarization layer 115 and the contact hole CH. The first anode 121a may be a layer for supplying positive holes to a light-emitting layer 122. In case that the display device 100 is a top emission type display device, the first anode 121a may include a reflective layer made of an opaque conductive material with high reflectance, for example, silver (Ag), aluminum (Al), gold (Au), molybdenum (Mo), tungsten (W), chromium (Cr), or an alloy thereof so that light emitted from the light-emitting layer 122 is reflected by the first anode 121a and propagates upward direction, e.g., in a direction toward a cathode 123 at the upper side. In addition, the first anode 121a may further include a transparent conductive layer disposed on the reflective layer and configured to supply positive holes to the light-emitting layer 122. Therefore, for example, the first anode 121a may have a structure in which a layer made of indium tin oxide (ITO), a layer made of molybdenum-titanium (MoTi), and a layer made of indium tin oxide (ITO) are stacked. However, the present specification is not limited thereto.

The first bank 116a may be disposed on the planarization layer 115 and the first anode 121a. The first bank 116a may define the light-emitting area EA of each of the subpixels SP by covering an edge of the first anode 121a of the light-emitting element 120. The first bank 116a may be made of an insulating material to insulate the first anodes 121a of the adjacent subpixels SP. In addition, the first bank 116a may be configured as a black bank with a high optical absorption rate to suppress a color mixture between the adjacent subpixels SP. For example, the first bank 116a may be made of polyimide resin, acrylic resin, or benzocyclobutene (BCB) resin. However, the present specification is not limited thereto.

Meanwhile, the second bank 116b is disposed on the first anode 121a in the contact hole CH. In a contact area CA, a step difference may be formed by a height h2 of the planarization layer because the contact hole CH is formed. In this case, an abnormal light-emitting area may occur because the light-emitting layer 122 is non-uniformly deposited because of the step difference. Therefore, the second bank 116b may cover the step difference so that the abnormal light-emitting area is not visually recognized. In this case, because the contact hole CH exposes a part of the top surface of the passivation layer 114, the second bank 116b may be disposed to cover the step difference between the passivation layer 114 and the planarization layer 115. Therefore, a height h1 of the second bank may be larger than a height of the passivation layer 114. In addition, the second bank 116b may have a shape having a step difference. Specifically, a width W2 of a portion of the second bank 116b adjacent to the planarization layer 115 may be larger than a width W1 of a portion adjacent to the passivation layer 114. Meanwhile, because the contact hole CH exposes a side surface SS of the planarization layer 115, the second bank 116b in the contact hole CH may be disposed to adjoin the first anode 121a disposed on the side surface SS of the planarization layer 115.

The second bank 116b may be formed as a residue remaining from etching during an open mask process or a halftone mask process for forming the first bank 116a. Therefore, the height h1 of the second bank 116b may be equal to or smaller than the height h2 of the planarization layer. For example, in case that the height h2 of the planarization layer 115 is about 2 μm and a size of the contact hole CH is 10×12 μm, the height h1 of the second bank may be about 0.2 μm. In case that a size of the contact hole CH is 5×7 μm, the height h1 of the second bank may be about 0.8 μm. However, the present specification is not limited thereto. That is, the second bank 116b may be disposed only in the contact hole CH without being disposed beyond the planarization layer 115 in the contact area CA, which may minimize an increase in the non-light-emitting area NEA. Meanwhile, the second bank 116b may be formed by the same process and made of the same material as the first bank 116a.

The light-emitting layer 122 may be disposed on the first anode 121a, the first bank 116a, and the second bank 116b. The light-emitting layer 122 is a layer that emits light by combining electrons and positive holes. In case that the display device 100 according to the embodiment of the present disclosure is an organic light-emitting display device, the light-emitting layer 122 may be an organic light-emitting layer including an organic material that spontaneously emits light. However, the present specification is not limited thereto.

The cathode 123 may be disposed on the light-emitting layer 122. The cathode 123 is a layer for supplying electrons to the light-emitting layer 122. For example, the cathode 123 may be made of a permeable or semi-permeable conductive material. For example, the cathode 123 may be made of a transparent conductive material such as indium tin oxide (ITO) or indium zinc oxide (IZO). However, the present specification is not limited thereto.

In the display device, the contact hole is formed to electrically connect the electrode disposed on the planarization layer and the pixel circuit disposed below the planarization layer. In this case, in case that the display device is an organic light-emitting display device, the light-emitting layer may not be uniformly deposited in the vicinity of the contact hole because of a step difference between the contact hole and the planarization layer. That is, an area with non-uniform luminance may be formed because of a thickness deviation of the light-emitting layer. The bank may be disposed on the contact hole to inhibit the area with non-uniform luminance from being visually recognized. In this case, because the bank is deposited by using a separate mask, a minimum spacing distance needs to be maintained in consideration of a process margin between the planarization layer and the bank. Therefore, a sufficient space for the process margin needs to be ensured, and the space corresponds to the non-light-emitting area. Therefore, the space for the process margin may degrade an aperture ratio.

In particular, this may be especially problematic for a high-PPI (pixel-per-inch) display device for implementing high resolution. That is, because one pixel of a high-resolution display device with high PPI has a small size, an increase in area occupied by the bank in the vicinity of the contact hole may greatly affect the aperture ratio.

Therefore, in the display device 100 according to the embodiment of the present specification, the second bank 116b is disposed in the contact hole CH in the contact area CA, such that the abnormal light-emitting area caused by the step difference of the planarization layer 115 is not visually recognized, which may improve the display quality.

In addition, in the display device 100 according to the embodiment of the present specification, the second bank 116b is disposed in the contact hole CH by using the residue, such that a process margin does not need to be ensured between the planarization layer 115 and the second bank 116b, which may improve the degree of design freedom.

In addition, in the display device 100 according to the embodiment of the present specification, the second bank 116b is disposed only in the contact hole CH, such that the non-light-emitting area of the contact area CA may be minimized, and the aperture ratio may be improved.

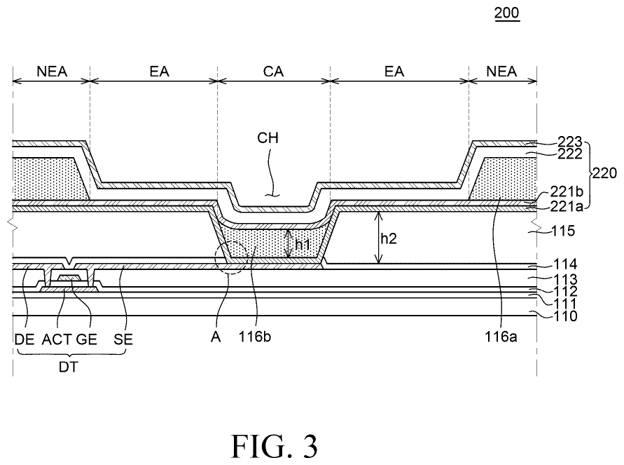

FIG. 3 is a cross-sectional view of a display device according to another embodiment of the present specification. A display device 200 in FIG. 3 is substantially identical in configuration to the display device 100 in FIGS. 1 and 2, except for a shape of the contact hole CH, the height h1 of the second bank 116b, and the presence or absence of a second anode 221b of a light-emitting element 220. Therefore, repeated descriptions of the identical components will be omitted.

With reference to FIG. 3, in the contact area CA, the contact hole CH may be formed in the passivation layer 114 and the planarization layer 115. In this case, with reference to area A, one end of the passivation layer 114 and one end of the planarization layer 115 may overlap in the contact hole CH. That is, unlike the display device 100 according to the embodiment of the present specification, a portion of the passivation layer 114, which is exposed by the contact hole CH, may be removed by dry etching in the display device 200 according to another embodiment of the present specification. That is, in the contact hole CH, the step difference between the passivation layer 114 and the planarization layer 115 may be mitigated.

Therefore, it is possible to reduce a thickness of the residue of the second bank 116b required to mitigate the step difference between the passivation layer 114 and the planarization layer 115. That is, in the display device 200 according to another embodiment of the present specification, the height h1 of the second bank 116b may be small, in comparison with the display device 100 according to the embodiment of the present specification. However, the present specification is not limited thereto.

In addition, because the second bank 116b is disposed in the contact hole CH formed in the passivation layer 114 and the planarization layer 115, the step difference between the passivation layer 114 and the planarization layer 115 may be mitigated, such that the second bank 116b may also be more gently disposed. Therefore, other constituent elements disposed on the second bank 116b may be uniformly disposed.

For example, the second anode 221b may be additionally disposed on the second bank 116b gently disposed to use the contact area CA as the light-emitting area. The further details will be described below.

Therefore, the height h1 of the second bank may be equal to or smaller than the height of the planarization layer 115. That is, a top surface TS1 of the second bank 116b may be positioned on the same plane as a top surface TS2 of the planarization layer 115 or disposed slightly below the top surface of the planarization layer 115.

Meanwhile, the second anode 221b may be disposed on a first anode 221a. Like the first anode 221a, the second anode 221b is a layer for supplying positive holes to a light-emitting layer 222. In this case, the second anode 221b is disposed on the second bank 116b in the contact hole CH. In comparison with the display device 100 illustrated in FIG. 2, the second anode 221b is disposed on the second bank 116b in the contact hole CH, and the light-emitting layer 222 and cathode 223 are sequentially disposed on the second bank 116b, such that the light-emitting layer 222 may emit light even in the contact hole CH. That is, an area of a portion of the light-emitting element 220, which has a flat surface, may be increased by using the second bank 116b that fills the contact hole CH. Therefore, the contact area CA may be used as the light-emitting area, and a problem of a decrease in light-emitting area caused by the contact area CA may be solved.

That is, in the display device 200 according to another embodiment of the present specification, the second bank 116b is disposed only in the contact hole CH by using the residue, such that a process margin does not need to be ensured between the planarization layer 115 and the second bank 116b, which may improve the degree of design freedom, minimize the non-light-emitting area, and improve the aperture ratio.

In particular, in the display device 200 according to another embodiment of the present specification, the passivation layer 114, which is exposed by the contact hole CH in the contact area CA, is subjected to dry etching, such that the step difference between the passivation layer 114 and the planarization layer 115 may be mitigated. Therefore, the step difference between the passivation layer 114 and the planarization layer 115 may be mitigated by disposing the second bank 116a by using a small amount of residue, such that the degree of design freedom may be improved.

In particular, in the display device 200 according to another embodiment of the present specification, the second anode 221b is additionally disposed on the second bank 116b in the contact hole CH, such that a portion of the light-emitting element 220, which has a flat surface, may be increased. That is, because light may be emitted even in the contact area CA, the light-emitting area may be increased, and the aperture ratio may be improved.

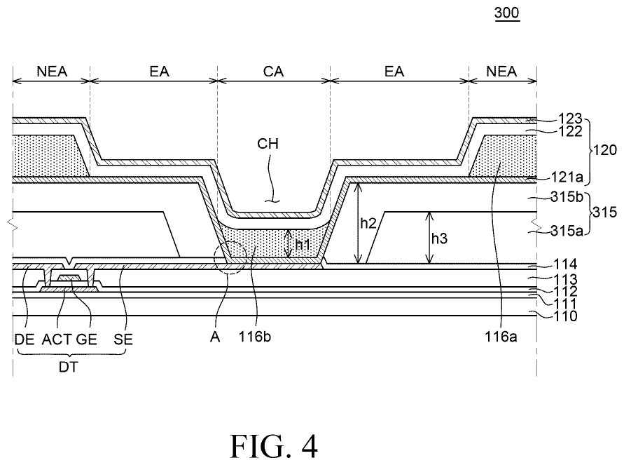

FIG. 4 is a cross-sectional view of a display device according to still another embodiment of the present specification. A display device 300 in FIG. 4 is substantially identical in configuration to the display device 200 in FIG. 3, except for a configuration of a planarization layer 315, the height h2 of the planarization layer, and the height h1 of the second bank. Therefore, repeated descriptions of the identical components will be omitted.

With reference to FIG. 4, the planarization layer 315 may include a first planarization layer 315a and a second planarization layer 315b.

Specifically, the first planarization layer 315a may be disposed on the passivation layer 114. The first planarization layer 315a may planarize an upper portion of the pixel circuit including the driving transistor DT. The first planarization layer 315a may be configured as a single layer or multilayer and made of benzocyclobutene or an acrylic-based organic material, for example. However, the present specification is not limited thereto.

The second planarization layer 315b may be disposed on the first planarization layer 315a. With reference to area A, the second planarization layer 315b may be disposed to cover a side surface of the first planarization layer 315a in the contact hole CH to suppress a situation in which the light-emitting layer 122 is deposited non-uniformly because of a step difference of the first planarization layer 315a and the luminous efficiency deteriorates. In this case, in the contact hole CH, one end of the second planarization layer 315b may overlap one end of the passivation layer 114. Meanwhile, the second planarization layer 315b may be made of the same material as the first planarization layer 315a. However, the present specification is not limited thereto.

In this case, because a height of the planarization layer 315 increases as the second planarization layer 315b is disposed, the amount of bank residue in the contact hole CH may increase. Therefore, a wide range of the height h1 of the second bank may be selected by adjusting an exposure dose. For example, the height h1 of the second bank may be equal to or smaller than the height h2 of the planarization layer and equal to or smaller than a height h3 of the first planarization layer.

In the display device 300 according to still another embodiment of the present specification, the second bank 116b is disposed only in the contact hole CH by using the residue, such that a process margin does not need to be ensured between the planarization layer 315 and the second bank 116b, which may improve the degree of design freedom, minimize the non-light-emitting area, and improve the aperture ratio.

In particular, in the display device 300 according to still another embodiment of the present specification, the second planarization layer 315b may be disposed to cover the side surface of the first planarization layer 315a, such that the planarization layer 315 may be gently inclined, and the light-emitting layer 122 may be uniformly deposited, which may improve the display quality.

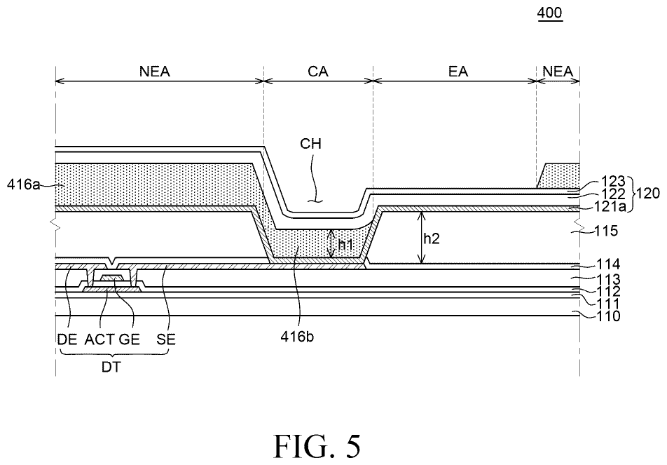

FIG. 5 is a cross-sectional view of a display device according to yet another embodiment of the present specification. A display device 400 in FIG. 5 is substantially identical in configuration to the display device 200 in FIG. 3, except for positions of the contact hole CH, a first bank 416a, and a second bank 416b. Therefore, repeated descriptions of the identical components will be omitted.

With reference to FIG. 5, the contact hole CH may be disposed adjacent to the non-light-emitting area NEA to minimize the non-light-emitting area. That is, the contact hole CH may be disposed adjacent to the first bank 416a. Therefore, one end of the first bank 416a and one end of the second bank 416b may be connected in the contact hole CH. That is, the first bank 416a and the second bank 416b may partially overlap each other, such that the non-light-emitting area may be minimized.

In the display device 400 according to yet another embodiment of the present specification, the second bank 416b is disposed only in the contact hole CH by using the residue, such that a process margin does not need to be ensured between the planarization layer 115 and the second bank 416b, which may improve the degree of design freedom.

In particular, in the display device 400 according to yet another embodiment of the present specification, the first bank 416a and the second bank 416b are disposed to overlap each other in the contact hole CH, such that the non-light-emitting area may be minimized, and the aperture ratio may be improved.

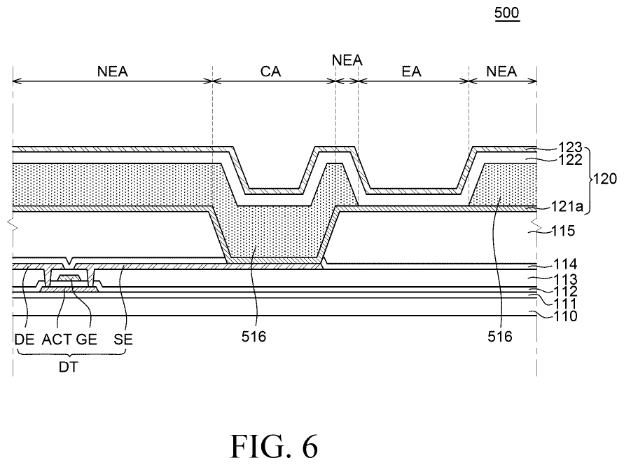

FIG. 6 is a cross-sectional view of a display device according to a comparative example. Unlike the display device according to the embodiment of the present specification, a display device 500 in FIG. 6 is a display device in which a bank 516 disposed in the contact area CA is not exposed by an open mask process or a halftone mask process.

With reference to FIG. 6, in the contact area CA, the bank 516 may not only be disposed in the contact hole CH, but also be disposed to extend to the top surface of the planarization layer 115 beyond the contact hole CH. Therefore, because light cannot be emitted in the contact area CA, the non-light-emitting area may be increased, and the aperture ratio may deteriorate.

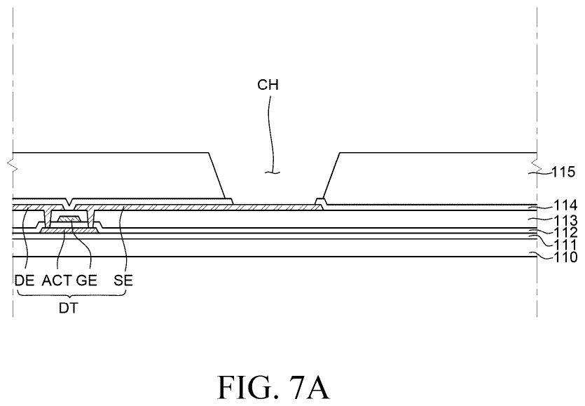

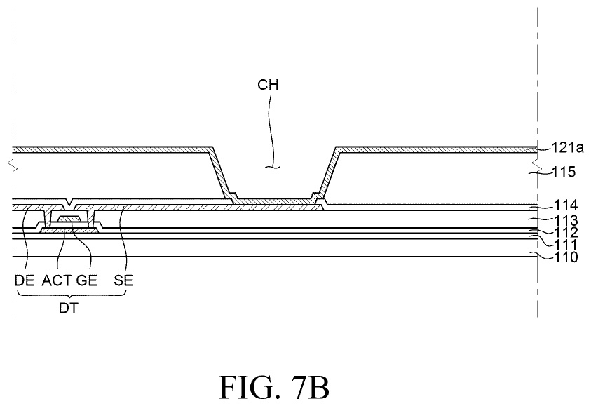

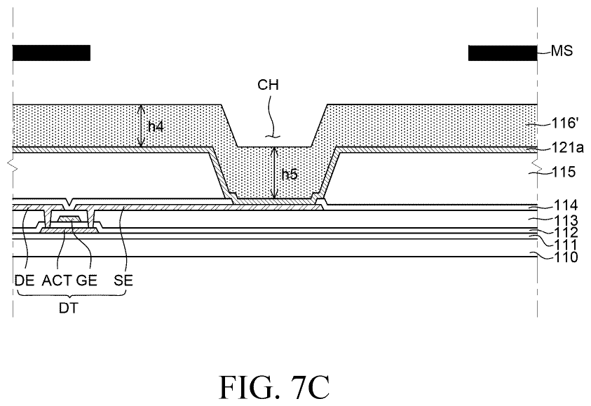

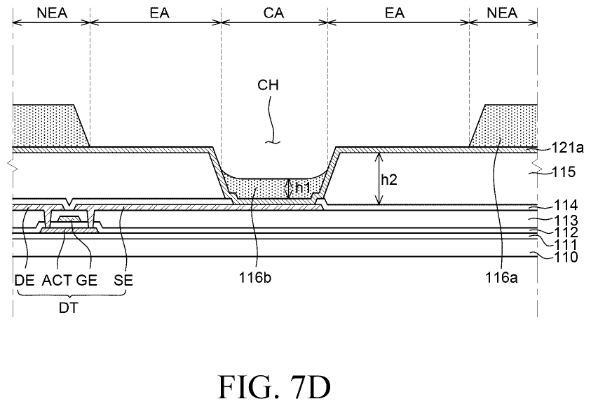

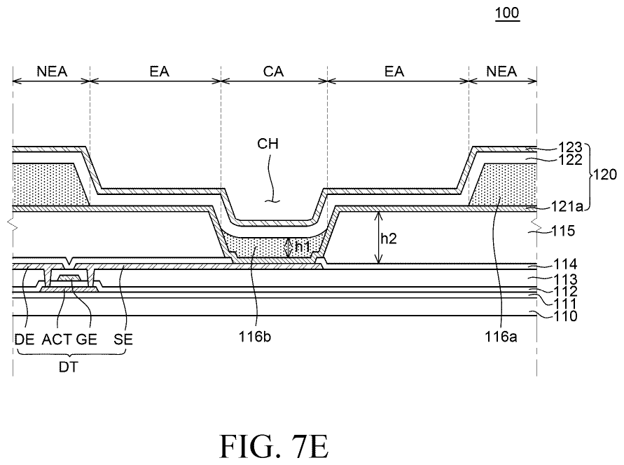

FIGS. 7A to 7E are process diagrams for explaining a method of manufacturing the display device according to the embodiment of the present specification.

First, with reference to FIG. 7A, a process of etching a part of the passivation layer 114 and a part of the planarization layer 115 may be performed to form the contact hole CH. Specifically, the process of forming the contact hole CH may be performed by sequentially performing a process of applying a photoresist onto the passivation layer 114, a process of selectively exposing the photoresist, a process of coating the passivation layer 114 with the planarization layer 115, a process of applying a photoresist onto the planarization layer 115, and a process of selectively exposing the photoresist.

Next, with reference to FIG. 7B, the first anode 121a may be deposited on the planarization layer 115 and the contact hole CH.

Next, a bank patterning process may be performed. First, with reference to FIG. 7C, a bank coating layer 116′ is formed by coating the planarization layer 115 and the contact hole CH with a bank forming composition. The bank forming composition may be a material for forming the first bank 116a and the second bank 116b and include polyimide resin, acrylic resin, or benzocyclobutene (BCB) resin and a curing composition. After the coating, the bank forming composition may flow into the contact hole CH because of a height difference between the contact hole CH and the top surface of the planarization layer 115. Therefore, immediately after the bank forming composition is applied, a height h5 of the bank coating layer 116′ in the contact hole CH may be larger than a height h4 of the bank coating layer 116′ on the planarization layer 115. For example, in case that the height h2 of the planarization layer 115 is about 2 μm and the size of the contact hole CH is 10×12 μm, the height h5 of the bank coating layer 116′ in the contact hole may be 2.03 μm, and the height h4 of the bank coating layer 116′ on the planarization layer 115 may be 1.13 μm. Meanwhile, in case that the size of the contact hole CH is 5×7 μm, the height h5 of the bank coating layer 116′ in the contact hole may be 2.42 μm, and the height h4 of the bank coating layer 116′ on the planarization layer 115 may be 1.06 μm. In this case, a mask MS may be disposed to etch the bank 116 by means of an open mask process. For example, a masking area of the mask MS is an area corresponding to the first bank 116a formed by a subsequent etching process and corresponds to the non-light-emitting area NEA, and an open area of the mask MS may correspond to the light-emitting area EA. In this case, the bank coating layer 116′ disposed in the contact hole CH may be exposed without being covered by the mask MS. Meanwhile, a halftone mask process may be performed instead of an open mask process.

With continued reference to FIG. 7D, a process of etching the bank coating layer 116′ may be performed. Therefore, the first bank 116a may be disposed on the top surface of the planarization layer 115, and the second bank 116b, which is the residue of the bank coating layer 116′ remaining by being exposed without a mask, may be disposed in an area in which the contact hole CH is disposed. As illustrated in FIG. 7C, because the height of the bank coating layer 116′ in the contact hole CH is larger than the height of the top surface of the planarization layer 115, the bank coating layer 116′ remains in the form of residue in the contact hole CH even though the same exposure dose is applied, such that the second bank 116b is formed. In this case, in order to cover the step difference between the passivation layer 114 and the planarization layer 115 in the contact hole CH, the exposure dose may be adjusted so that a thickness of the residue of the bank coating layer 116′ is equal to or larger than the passivation layer 114.

Lastly, with reference to FIG. 7E, the light-emitting layer 122 and the cathode 123 are sequentially deposited on the first anode 121a, the first bank 116a, and the second bank 116b, such that the process of manufacturing the display device 100 may be completed.

The exemplary embodiments of the present disclosure can also be described as follows:

According to an aspect of the present disclosure, there is provided a display device. The display device includes a substrate comprising a plurality of subpixels; a driving transistor in each of the plurality of subpixels; a passivation layer on the driving transistor; a planarization layer on the passivation layer; a contact hole formed in the passivation layer and the planarization layer to expose a source electrode of the driving transistor; a first anode on a top surface of the planarization layer and the contact hole; a first bank configured to cover an edge of the first anode; and a second bank disposed on the first anode in the contact hole. A height of the second bank is equal to or smaller than a height of the planarization layer.

A height of the second bank may be larger than a height of the passivation layer.

The second bank in the contact hole may contact the first anode disposed on a side surface of the planarization layer.

The contact hole may expose a part of a top surface of the passivation layer, and the second bank may cover a step difference between the passivation layer and the planarization layer.

The second bank may have a shape having the step difference, and a width of a portion of the second bank, which is adjacent to the planarization layer, is larger than a width of a portion adjacent to the passivation layer.

One end of the passivation layer may overlap one end of the planarization layer in the contact hole.

The display device may further comprise a second anode on the first anode. The second anode is disposed on the second bank in the contact hole.

The planarization layer may comprise a first planarization layer on the passivation layer; and a second planarization layer on the first planarization layer. The second planarization layer may cover a side surface of the first planarization layer in the contact hole.

One end of the second planarization layer may overlap one end of the passivation layer in the contact hole.

The plurality of subpixels may comprise a light-emitting area and a non-light-emitting area, and the contact hole may be disposed in the light-emitting area.

The plurality of subpixels may comprise a light-emitting area and a non-light-emitting area, the contact hole is disposed adjacent to the non-light-emitting area, and one end of the first bank may be connected to the second bank in the contact hole.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a substrate having a plurality of subpixels;
a driving transistor in each of the plurality of subpixels;
a passivation layer on the driving transistor;
a planarization layer on the passivation layer;
a contact hole in the passivation layer and the planarization layer to expose a source electrode of the driving transistor;
a first anode on a top surface of the planarization layer and the contact hole;
a first bank configured to cover an edge of the first anode; and
a second bank on the first anode in the contact hole,
wherein a height of the second bank is equal to or smaller than a height of the planarization layer.

2. The display device of claim 1, wherein a height of the second bank is larger than a height of the passivation layer.

3. The display device of claim 1, wherein the second bank adjoins the first anode disposed on a side surface of the planarization layer in the contact hole.

4. The display device of claim 1, wherein the contact hole exposes a part of a top surface of the passivation layer, and the second bank covers a step difference between the passivation layer and the planarization layer.

5. The display device of claim 4, wherein the second bank has a shape having the step difference, and a width of a portion of the second bank, which is adjacent to the planarization layer, is larger than a width of a portion adjacent to the passivation layer.

6. The display device of claim 1, wherein one end of the passivation layer overlaps one end of the planarization layer in the contact hole.

7. The display device of claim 6, further comprising:
a second anode on the first anode,
wherein the second anode is on the second bank in the contact hole.

8. The display device of claim 1, wherein the planarization layer comprises:
a first planarization layer on the passivation layer; and
a second planarization layer on the first planarization layer, and
wherein the second planarization layer covers a side surface of the first planarization layer in the contact hole.

9. The display device of claim 8, wherein one end of the second planarization layer overlaps one end of the passivation layer in the contact hole.

10. The display device of claim 1, wherein the plurality of subpixels comprises a light-emitting area and a non-light-emitting area, and the contact hole is disposed in the light-emitting area.

11. The display device of claim 1, wherein the plurality of subpixels comprises a light-emitting area and a non-light-emitting area, the contact hole is disposed adjacent to the non-light-emitting area, and one end of the first bank is connected to the second bank in the contact hole.

12. The display device of claim 1, wherein the shape of the contact hole is an inversely tapered shape.

13. The display device of claim 8, wherein a height of the second bank is equal to or smaller than a height of the first planarization layer.

14. A method of manufacturing the display device of claim 1, the method comprises:
etching a part of the passivation layer and a part of the planarization layer to form the contact hole;
depositing the first anode on the planarization layer and the contact hole;
forming a bank coating layer by coating the planarization layer and the contact hole, wherein a height of the bank coating layer in the contact hole is larger than a height of the bank coating layer on the planarization layer; and
etching the bank coating layer to form the first bank and the second bank.
